(19) United States
(12) Patent Application Publication
(10) Pub. No.: US 2008/0146017 A1
(43) Pub. Date: Jun. 19, 2008

(54) METHOD FOR MANUFACTURING SEMICONDUCTOR DEVICE

(75) Inventor: Juri KATO, Chino (JP)

Correspondence Address: HARNESS, DICKEY & PIERCE, P.L.C., P.O. BOX 828, BLOOMFIELD HILLS, MI, 48303, US

(73) Assignee: SEIKO EPSON CORPORATION, Tokyo (JP)

(21) Appl. No.: 11/954,414

(22) Filed: Dec. 12, 2007

(30) Foreign Application Priority Data
Dec. 19, 2006 (JP) 2006-341647

(51) Int. Cl. H01L 21/4763

(52) U.S. Cl. 438/618

(57) ABSTRACT

A method for manufacturing a semiconductor device comprises: (a) stacking a first semiconductor layer and a second semiconductor layer serially on a semiconductor substrate; (b) providing a protection film above the second semiconductor layer; (c) providing a first groove that penetrates the protection film, the second semiconductor layer, and the first semiconductor layer and surrounds an element region in plan view so as to define a boundary between the element region and a remaining region, by partially etching the protection film, the second semiconductor layer, and the first semiconductor layer; (d) providing a support film so as to fill the first groove and cover the second semiconductor layer; (e) providing a second groove that provides a support including the support film and exposes the first semiconductor layer from under the second semiconductor layer, by partially etching the support film in a condition that the support film is more readily etched than the protection film; and (f) providing a cavity between the semiconductor substrate and the second semiconductor layer of the element region by etching the first semiconductor layer via the second groove in a condition that the first semiconductor layer is more readily etched than the second semiconductor layer.

The entire disclosure of Japanese Patent Application No. 2006-341647, filed Dec. 19, 2006 is expressly incorporated by reference herein.

### BACKGROUND

1. Technical Field

Several aspects of the present invention relates to a method for manufacturing a semiconductor device, particularly to a technique that enables fabrication of a silicon-on-insulator (SOI) layer showing less variation in the area, the planar shape, or the like when partially providing the SOI structure to a semiconductor substrate.

2. Related Art

The related art of this kind are, for example, JP-A-2005-354024 and JP-A-2006-41331, which disclose a technique that enables fabrication of a SOI transistor (i.e., a technique of SBSI, or separation by boding silicon islands) at low costs by partially providing the SOI structure on a bulk substrate.

In the SBSI technique, a Si/SiGe layer is fabricated on a Si substrate, and, with reference to in FIG. 15A, a support hole h′ is provided. The support hole h′ penetrates the Si/SiGe layer, and its bottom surface is composed of the Si substrate. Then, with reference to FIG. 15B, a support 122 is provided so as to fill the support hole h′ and cover the surface of the Si layer. Referring to FIG. 15C, provided next is a groove (i.e., a SiGe removing hole) H′ that exposes the side surfaces of the SiGe layer from under the Si layer that is supported by the support 122. Then, by wet-etching the SiGe layer via this SiGe removing hole H′, a cavity is provided between the Si substrate and the Si layer. Thereafter, a buried oxide (BOX) layer composed of, e.g., SiO₂ film is provided between the Si substrate and the Si layer by thermal oxidation or chemical vapor deposition (CVD).

In the SBSI technique of the related art, the area of the Si layer (i.e., an element region) provided on the BOX layer is not very large, and the shape of the Si layer in plan view is often a simple rectangle with not a large difference between the length and the width.

However, with recent improvement in the etching ratio of SiGe to Si, it has become possible to provide the element region having a larger area. Also, with the SBSI technique being more widely applied, as applied in a method for manufacturing a static random access memory (SRAM), the shape in plan view (referred also as a “planar shape”) of the element region is becoming more complex. For example, the planar shape of the element region is selected from: a rectangle whose long side is notably longer than the short side, a letter “L” shape, a letter “T” shape, a shape of “tandem H,” and a shape of “+.” The area of the element region also varies from large to small. Thus, while it has been possible in the past to sufficiently support the Si layer by arranging the support holes h′ only along the short sides of the element region as shown in FIG. 15C, there are now an increasing number of cases in which the Si layer is not sufficiently supported unless the support holes are arranged along both the short and long sides of the element region.

Also, in accordance with the above, although the area and the planar shape of the element region have not been greatly affected even when the position of the support hole h′ did not match perfectly with that of the SiGe removing hole H′, there are now more cases in which the area and the planar shape of the element region fluctuate greatly if the positions of the support hole h′ and the SiGe removing hole H′ do not match even slightly. For example, when a gate electrode 141 of a metal-oxide-semiconductor (MOS) transistor, shown in bold lines in FIG. 16A, is arranged so as to lie parallel to the short side of the element region and directly above a support hole h′ 1 that is placed along the long side of the element region, a channel width W of the MOS transistor becomes equal to a distance between the support hole h′ 1 and the SiGe removing hole H′. If the entire support hole h′ 1 moves down as shown in FIG. 16B or moves up as shown in FIG. 16C, the channel width W becomes short or long. Consequently, new problems are exposed along with the development of the SBSI technology.

### SUMMARY

An advantage of the invention is to provide a method for manufacturing a semiconductor device that enables fabrication of a SOI layer showing less variation in the area, the planar shape, or the like when providing the SOI structure partially to a semiconductor substrate.

According to an aspect of the invention, a method for manufacturing a semiconductor device includes: (a) stacking a first semiconductor layer and a second semiconductor layer serially on a semiconductor substrate; (b) providing a protection film above the second semiconductor layer; (c) providing a first groove that penetrates the protection film, the second semiconductor layer, and the first semiconductor layer and surrounds an element region in plan view so as to define a boundary between the element region and a remaining region, by partially etching the protection film, the second semiconductor layer, and the first semiconductor layer; (d) providing a support film so as to fill the first groove and cover the second semiconductor layer; (e) providing a second groove that provides a support including the support film and exposes the first semiconductor layer from under the second semiconductor layer, by partially etching the support film in a condition that the support film is more readily etched than the protection film; and (f) providing a cavity between the semiconductor substrate and the second semiconductor layer of the element region by etching the first semiconductor layer via the second groove in a condition that the first semiconductor layer is more readily etched than the second semiconductor layer.

For example, the “first semiconductor layer” as named herein is SiGe, and the “second semiconductor layer” is Si. Also, the “support film” is a SiO₂ film, for example, and the “protection film” is a Si₃N₄ film, for example.

By the semiconductor device manufacturing method of this aspect of the invention, the element region may be defined upon formation of the first groove, and, in the step of providing the second groove, the second semiconductor layer of the element region may be protected from being etched by use of the protection film. Therefore, it is possible to reduce variation that occurs in processing the element region (e.g., variation in the area, the planar shape, or the like), because the second semiconductor layer of the element region remains unetched even if there is a slight positional shift in the patterning by photolithography in the step of providing the second groove.

In the method for manufacturing a semiconductor device, it is preferable that step (e) includes: providing, on the support film, a resist pattern that opens both directly above a region for providing the second groove and directly above an end, located at a side adjacent to the second groove, of the element region adjacent to the region for providing the second groove; and etching the support film using the resist pattern as a mask. In this case, the second groove may be provided in a self-aligning manner, because the protection film covering the end, located at a side adjacent to the second groove, of the element region acts as a mask when providing the second groove.

In the method for manufacturing a semiconductor device, it is preferable that the shape of the element region in plan view be any one shape out of a “tandem H” shape, a letter “T” shape, a letter “L” shape, and a “+” shape, or any combination thereof; and that, in the step (e), the support film remains in the first groove adjacent to a letter end of the element region. In this case, it is possible to strengthen the support of the second semiconductor layer at the letter ends of the shape of “tandem H,” letter “T.” letter “L,” or “+,” and to prevent the second semiconductor layer from bending or peeling.

In the method for manufacturing a semiconductor device, it is preferable that the shape of the element region in plan view include the “+” shape, and that, in the step (e), the support film remains in the first groove adjacent to an intersecting region at a center of the “+” shape. In this case, it is possible to strengthen the support of the second semiconductor layer at the intersecting region at the “+” shaped center included in the element region, and to prevent the second semiconductor layer from bending or peeling.

### BRIEF DESCRIPTION OF THE DRAWINGS

The invention will be described with reference to the accompanying drawings, wherein like numbers reference like elements.

FIGS. 1A to 1C are diagrams (1) showing a method for manufacturing a semiconductor device according to a first embodiment.

FIGS. 2A to 2C are diagrams (2) showing the method for manufacturing a semiconductor device according to the first embodiment.

FIGS. 3A to 3C are diagrams (3) showing the method for manufacturing a semiconductor device according to the first embodiment.

FIGS. 4A to 4C are diagrams (4) showing the method for manufacturing a semiconductor device according to the first embodiment.

FIGS. 5A to 5C are diagrams (5) showing the method for manufacturing a semiconductor device according to the first embodiment.

FIGS. 6A to 6C are diagrams (6) showing the method for manufacturing a semiconductor device according to the first embodiment.

FIGS. 7A to 7C are diagrams (7) showing the method for manufacturing a semiconductor device according to the first embodiment.

FIGS. 8A to 8C are diagrams (8) showing the method for manufacturing a semiconductor device according to the first embodiment.

FIGS. 9A to 9C are diagrams (9) showing the method for manufacturing a semiconductor device according to the first embodiment.

FIGS. 10A and 10B are diagrams showing an example of alignment of a photomask 90 using an alignment mark M.

FIGS. 11A and 11B are diagrams (1) showing one exemplary shape of an element region according to a second embodiment.

FIG. 12 is a diagram (1) showing one exemplary shape of an element region according to other embodiment.

FIGS. 13A to 13C are diagrams (2) showing exemplary shapes of the element region according to the other embodiment.

FIG. 14 is a diagram (3) showing one exemplary shape of the element region according to the other embodiment.

FIGS. 15A to 15C are diagrams showing an example of related art.

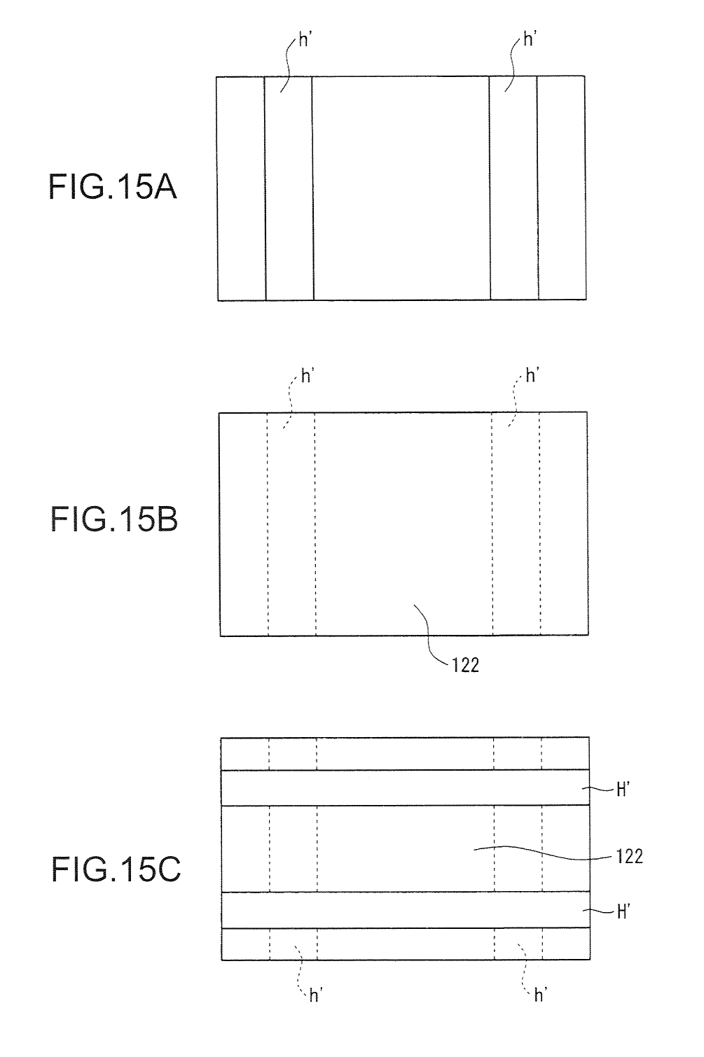

FIGS. 16A to 16C are diagrams showing problems in the example of the related art.

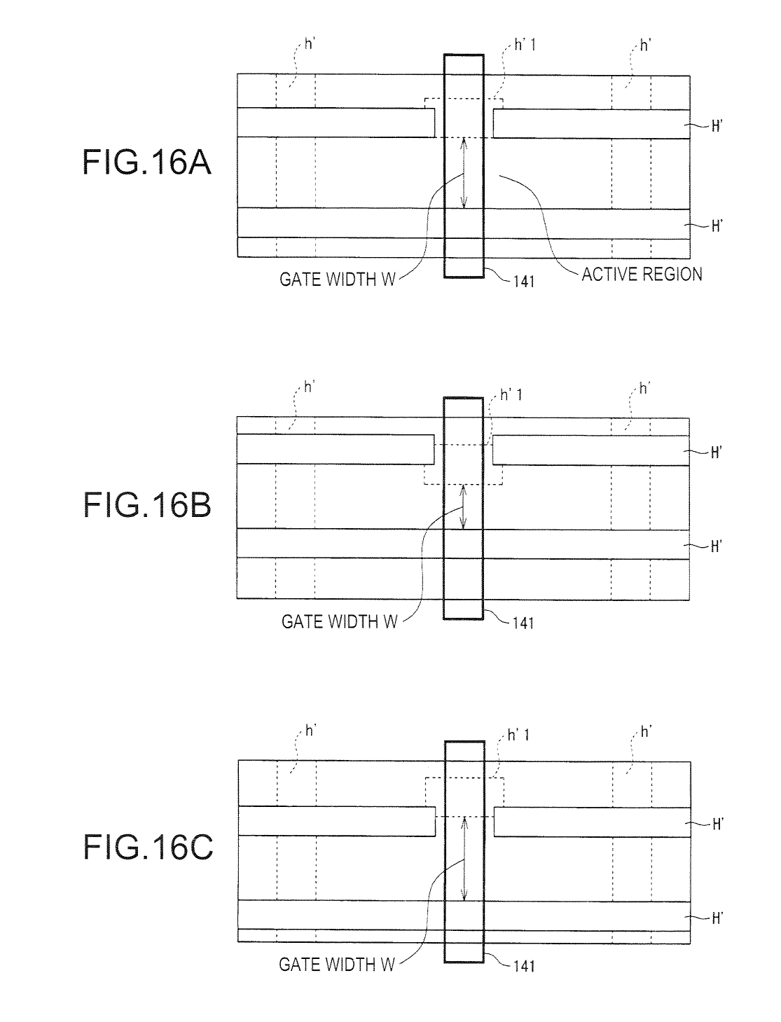

### DESCRIPTION OF EXEMPLARY EMBODIMENTS

Embodiments of the invention will now be described with reference to the drawings.

### 1. First Embodiment

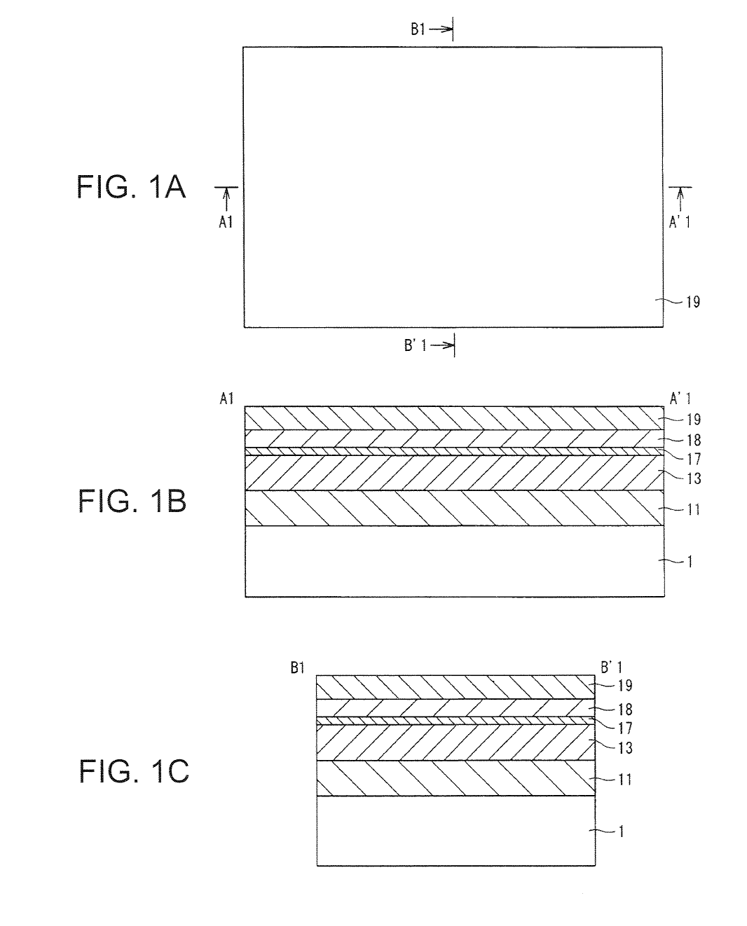

FIGS. 1A through 9C are diagrams showing the method for manufacturing a semiconductor device of the first embodiment of the invention. Drawings A of FIGS. 1 through 9 are plan diagrams. Drawings B of FIGS. 1 through 9 are sectional diagrams taken on lines A1-A′1 through A9-A′9 of drawings A of FIGS. 1 through 9. Drawings C of FIGS. 1 through 9 are sectional diagrams taken on lines B1-B′1 through B9-B′9 of drawings A of FIGS. 1 through 9.

First, with reference to FIGS. 1A through 1C, a single-crystal silicon buffer (Si-buffer) layer (not shown) is provided on a Si substrate 1; a single-crystal silicon germanium (SiGe) layer 11 is provided on the Si-buffer layer; and a single-crystal silicon (Si) layer 13 is provided on the SiGe layer 11. These Si-buffer layer, SiGe layer 11, and Si layer 13 are successively provided by, for example, epitaxial growth. Then, a SiO₂ film 17 is provided on the entire upper surface of the Si substrate 11; a silicon nitride (Si₃N₄) film 18 is provided on the SiO₂ film 17; and a SiO₂ film 19 is provided on the Si₃N₄ film 18. These SiO₂ film 17, the Si₃N₄ film 18, and the SiO₂ film 19 are provided by chemical vapor deposition (CVD), for example.

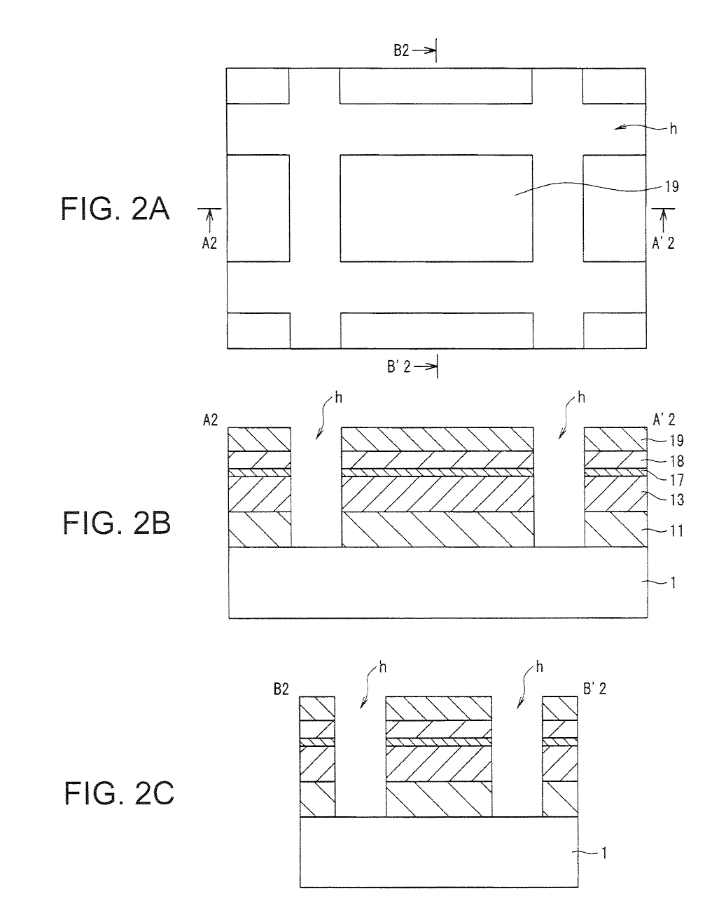

Then, with reference to FIGS. 2A through 2C, the SiO₂ film 19, the Si₃N₄ film 18, the SiO₂ film 17, the Si layer 13, the SiGe layer 11, and the Si-buffer layer (now shown) are each partially etched using photolithography and etching techniques. As a result, with reference to FIGS. 2A through 2C, a support hole h of which bottom surface is the Si substrate 1 is provided at a region planarly overlapping with an element separation region (i.e., a region at which the SOI structure is not provided). In this etching process, the etching may be stopped at the surface of the Si substrate 1, or the Si substrate 1 may be over-etched to produce a recess.

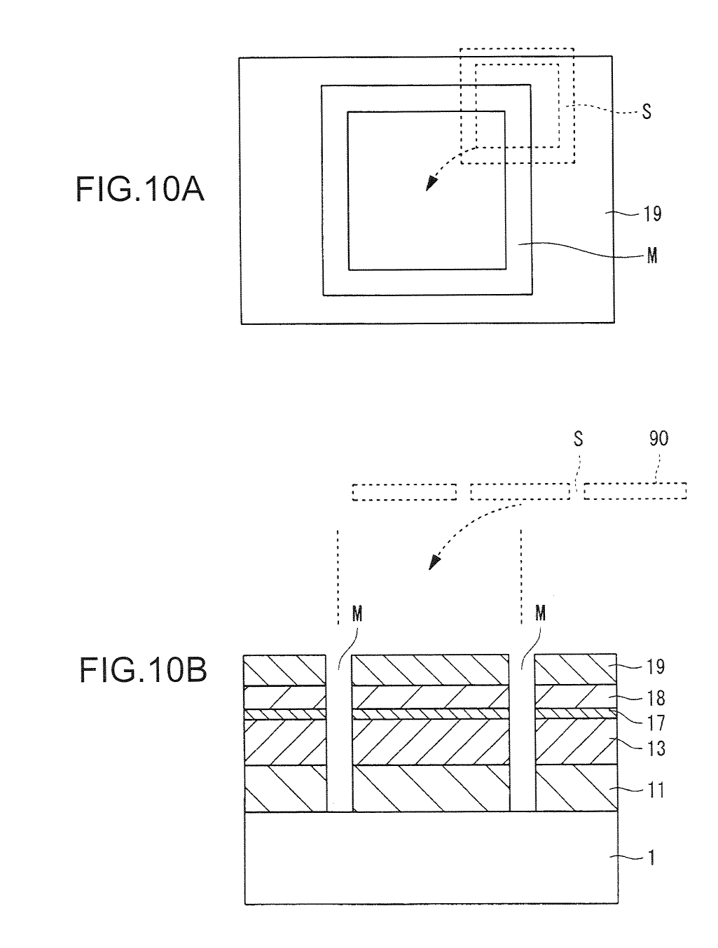

In the present embodiment, in the process of providing the support hole h, it is preferable to use a photomask having a slit which is used for alignment mark formation. Accordingly, when a support hole h 1 is provided, an alignment mark M such as the example shown in FIGS. 10A and 10B is provided simultaneously. The planar shape of the alignment mark M may be, for example, a hollow square as the example shown in FIG. 10A or a cross. Preferably, the shape includes a line segment in a direction X and a line segment in a direction Y perpendicular to the direction N. The position of the alignment mark M may be set as desired, such as at four corners of a wafer, a scribe line, or an element separation region of the chip. The number of the alignment mark M may also be chosen as desired.

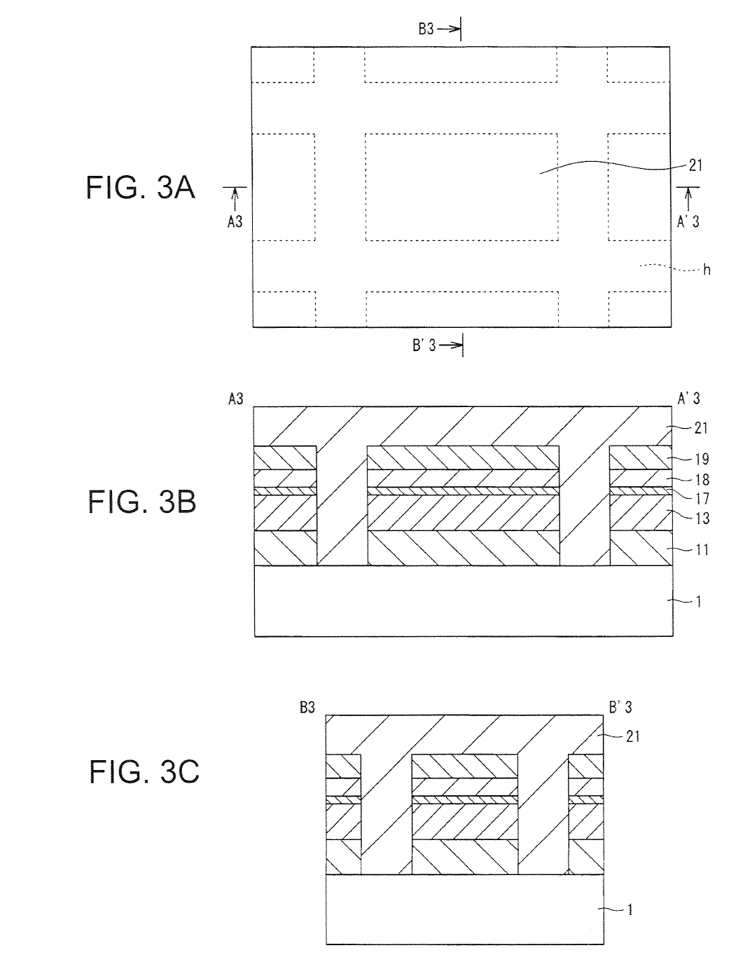

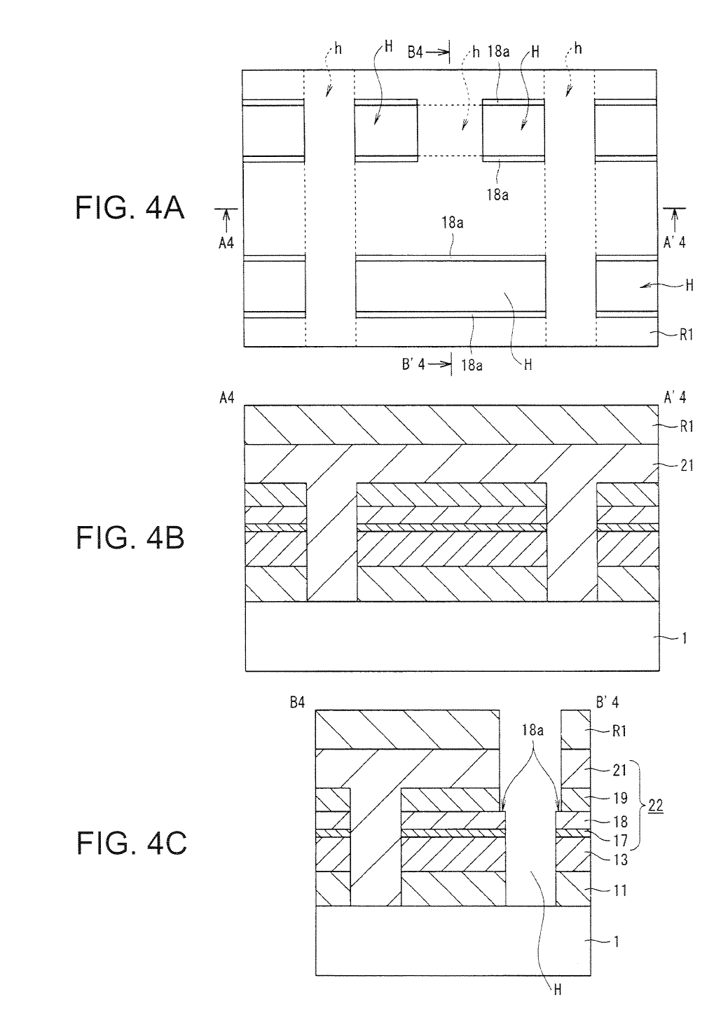

After providing the support hole h and the alignment mark M simultaneously as described, a resist pattern (not shown) is removed. Thereafter, referring to FIGS. 3A to 3C, a SiO₂ film 21 is provided on the entire upper surface of the Si substrate 1 while filling the support hole h. The SiO₂ film 21 is provided by CVD, for example. Then, referring to FIGS. 4A to 4C, a resist pattern R1 is provided on the SiO₂ film 21 through photolithography and, using this resist pattern R1 as a mask, the SiO₂ films 21 and 19 are each partially etched.

In the embodiment, in the process of providing the resist pattern R1, it is preferable to align the photomask to the wafer by using, as a mark, the alignment mark provided simultaneously with the support hole h, instead of using a local-oxidation-of-silicon (LOCOS) film (not shown) or the like as in the prior art. For example, referring to FIGS. 10A and 10B, a photomask 90 used for formation of the SiGe removing hole H has a slit S (that corresponds to the position at which the alignment mark M is arranged) that is used for the alignment. The photomask 90 is aligned to the wafer so that the slit S lies inside the alignment mark M in plan view. As a result, the SiGe removing hole H is provided with a minor positional shift relative to the support hole h. Then, referring to FIG. 4C, the side surfaces of the SiGe layer 11 and the Si layer 13 are exposed to the inner walls of the SiGe removing hole H.

Referring to FIGS. 10A and 10B, the slit S provided in the photomask 90 may have a planar shape of, for example, a hollow square or a cross, preferably including a line segment in a direction X and a line segment in a direction Y perpendicular to the direction X. By making the planar shape of the slit S to be identical with that of the alignment mark M, and by including the line segments in the X and Y directions in its shape, the precision in aligning the photomask to the wafer increases with only a little positional shift from the X and Y directions.

Also, in the embodiment, the SiO₂ film 21 may be etched by dry etching that exhibits higher selectivity with respect to the Si₃N₄ film (i.e., the etching rate of the SiO₂ film is extremely higher than that of the Si₃N₄ film) or wet etching with hydrofluoric acid that exhibits higher selectivity with respect to the Si₃N₄ film. As a result, referring to FIGS. 4A to 4C, a support 22 composed of the SiO₂ films 21 and 19, the Si₃N₄ film 18, and the SiO₂ film 17 is provided together with the groove (i.e., SiGe removing hole) H of which bottom surface is composed of the Si substrate 1. In this process of providing the SiGe removing hole H, the etching may be stopped at the surface of the Si substrate 1, or the Si substrate 1 may be over-etched so as to provide a recess.

Referring to FIG. 4C, the shape of the resist pattern R1 used for etching of the SiO₂ film 21 is such that opens directly above the region for providing the SiGe removing hole H and the periphery thereof and that covers the remaining region. More specifically, the resist pattern R1 has a shape that opens directly above the region for providing the SiGe removing hole H and directly above an end (adjacent to the SiGe removing hole H) of the element region adjacent to the SiGe removing hole H and that covers the remaining region. By etching the SiO₂ films 21 and 19 using the resist pattern R1 having such a shape, an end 18a of the Si₃N₄ film 18 is exposed from under the resist pattern R1 as shown in FIGS. 4A and 4C. After the end 18a is exposed, the SiO₂ film 21 (filling the support hole h) is etched using this end 18a as a mask.

Because the end 18a of the Si₃N₄ film 18 is used as a mask, the SiGe removing hole H is provided in a self-aligning manner below the SiO₂ film 19 even if the photomask is not aligned well to the wafer for some reason (that is, even if the resist pattern R1 is shifted in position). Therefore, the alignment of the resist pattern R1 is allowed to have a margin of error.

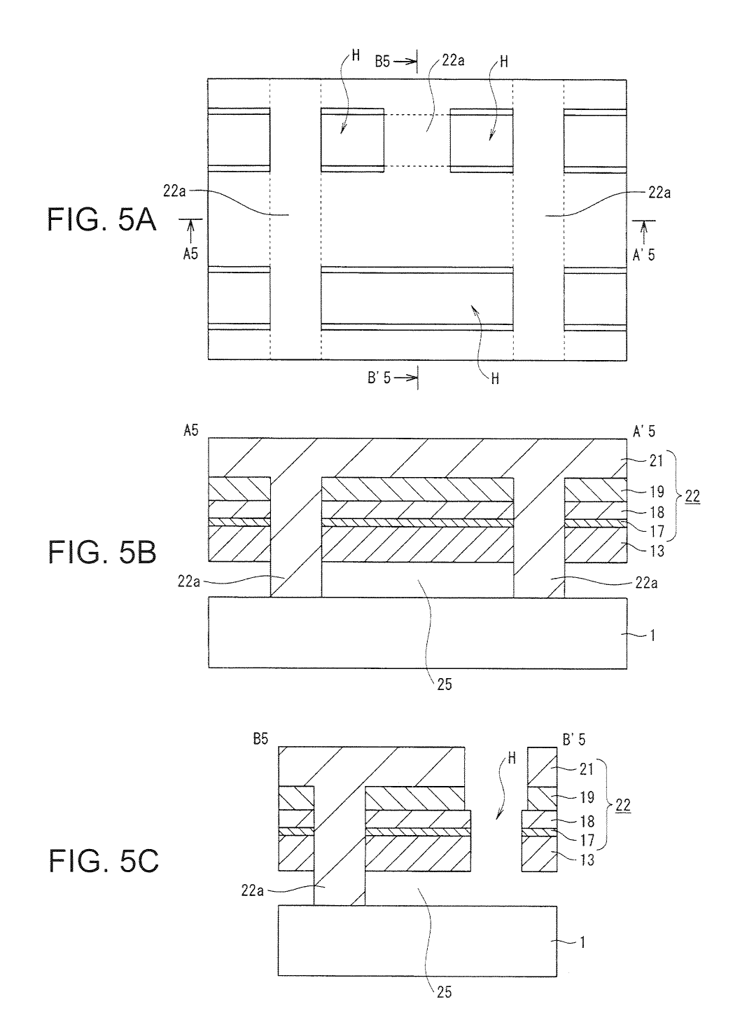

Next, with reference to FIGS. 4A to 4C, the SiGe layer 11 is selectively etched by bringing the side surface of each of the Si layer 13 and the SiGe layer 11 to come in contact with a fluoronitric acid solution via the SiGe removing hole H. As a result, referring to FIGS. 5A to 5C, a cavity 25 is provided between the Si layer 13 and the Si substrate 1. In the wet etching using the fluoronitric acid solution, it is possible to etch and remove only the SiGe layer 11 and to leave the Si layer 13 unetched, because the etching rate of SiGe is higher compared to Si (that is, the etch selectivity of SiGe is higher with respect to Si). Now that the cavity 25 is provided, the upper and side surfaces of the Si layer 13 are supported by the support 22.

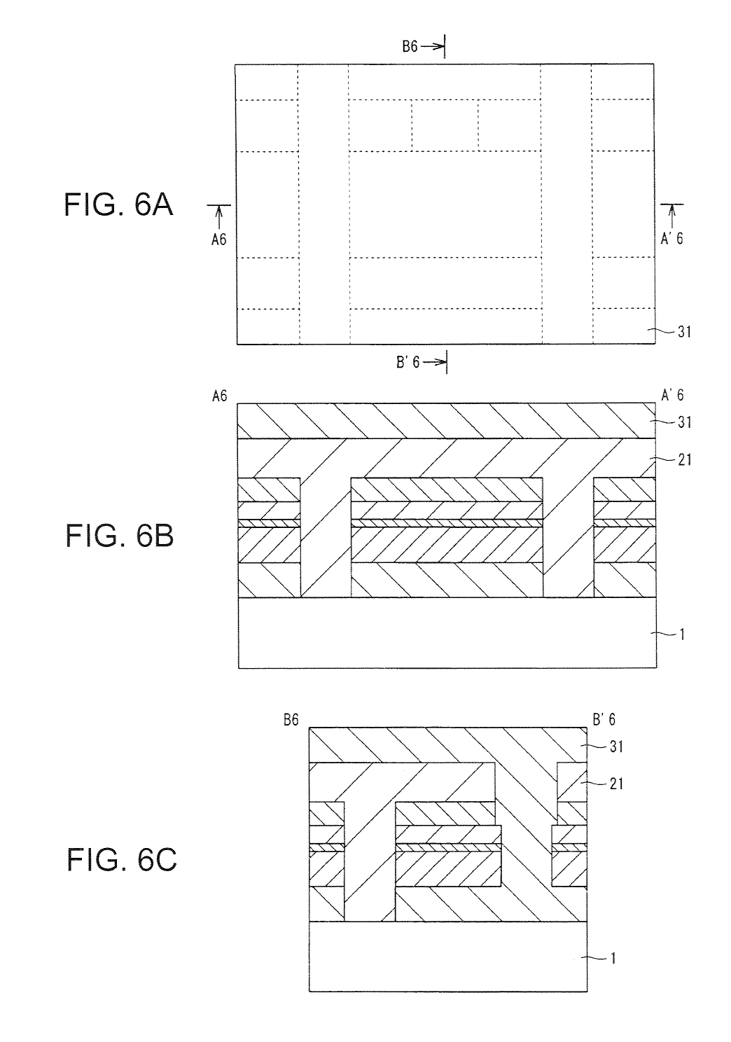

Then, with reference to FIGS. 5A to 5C, the Si substrate 1 is thermally oxidized to provide a SiO₂ film (not shown) on each surface of the Si substrate 1 and the Si layer 13 facing the cavity 25. Then, referring to FIGS. 6A to 6C, an insulating film 31 is provided on the entire surface of the Si substrate 1 so as to fill the SiGe removing hole H. The insulating film 31 is a SiO₂ film or a Si₃N₄ film, for example. By such thermal oxidation, or by thermal oxidation and CVD, the insulating film of SiO₂ or the like is completely buried in the cavity 25.

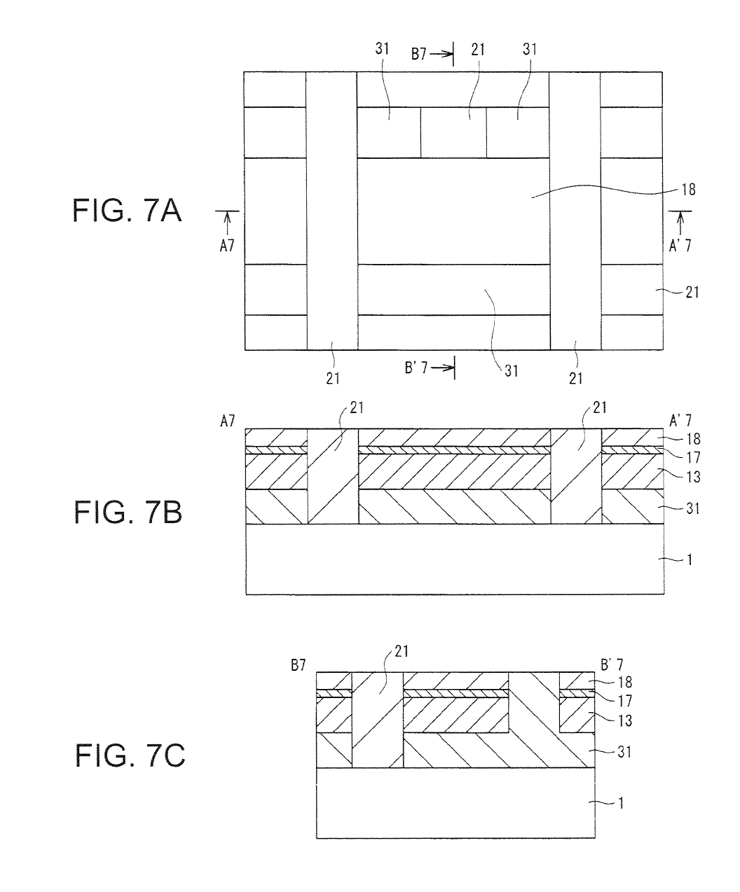

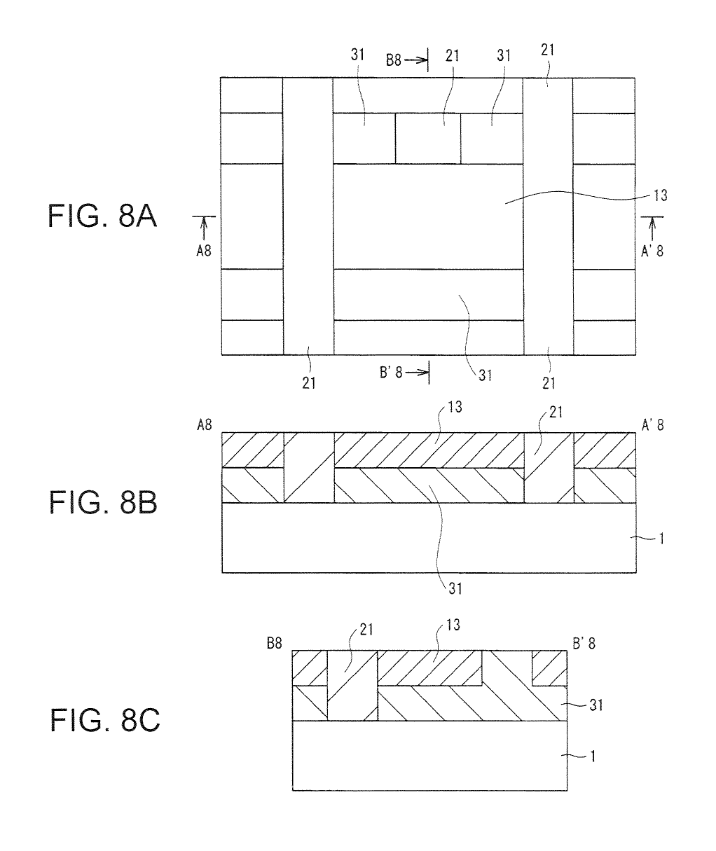

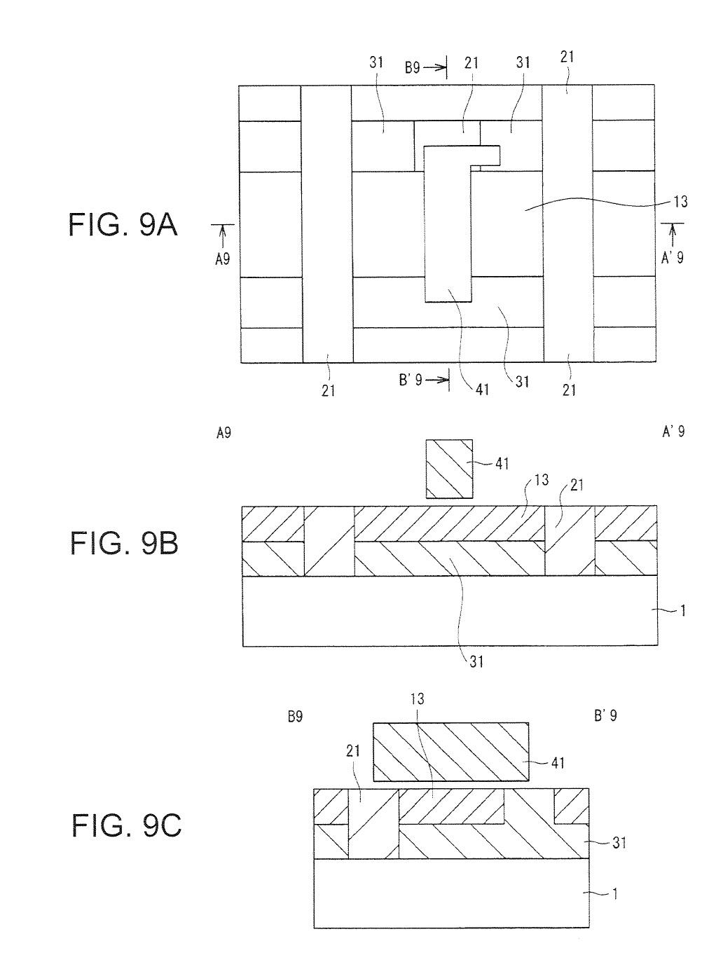

Thereafter, the insulating film 31 and the SiO₂ films 21 and 19 covering the entire surface of the Si substrate 1 are planarized by, e.g., chemical-mechanical polishing (CMP) and removed so as to expose the surface of the Si₃N₄ film 18 as shown in FIGS. 7A to 7C. In this CMP, the Si₃N₄ film 18 acts as a stopper against a polishing pad. Then, the Si₃N₄ film 18 is wet-etched using, e.g., a heat phosphoric acid and removed, and the SiO₂ film 13 is wet-etched using, e.g., a dilute hydrofluoric acid solution and removed so as to expose the surface of the Si layer 13 as shown in FIGS. 8A to 8C. As a result, the SOI structure is provided to the Si substrate 1. After completing the SOI structure, referring to FIGS. 9A to 9C, a gate electrode 41 is provided above the Si layer 13 of the SOI structure, with a gate insulating film (not shown) interposed therebetween. A MOS transistor is thereby provided.

As described, according to the embodiment of the invention, it is possible to define the element region at the time of providing the support hole h and, in the step of providing the SiGe removing hole H, to prevent the Si layer 13 of the element region from being etched by use of the Si₃N₄ film 18 for protection. Because the Si layer 13 of the element region is not etched even if the patterning by photolithography experiences a slight positional shift when providing the SiGe removing hole H, it is possible to reduce variation (e.g., variation in the area, the planar shape, or the like) that occurs in processing the element region.

In the embodiment, it is intended to reduce the positional shift of the resist pattern R1 with respect to the support hole h by simultaneously patterning the support hole h and the alignment mark M using the same photomask and by patterning the SiGe removing hole H using this alignment mark M as a mark. However, in the embodiments of the invention, the use of the alignment mark M is not essential. For example, the support hole h and the SiGe removing hole H may both be patterned using the LOCOS film or the like as a mark.

The reason for above is that, because the end 18a of the Si₃N₄ film 18 acts as a mask when providing the SiGe removing hole H, the SiGe removing hole H is provided in a self-aligning manner. In the embodiment of the invention, because the SiGe removing hole H can be provided in a self-aligning manner, the Si layer 13 of the element region remains unetched even if the resist pattern R1 is slightly shifted in position, and it is possible to reduce the variation that occurs in processing the element region.

### 2. Second Embodiment

In the first embodiment above, the planar shape of the element region is rectangular. Also, in the process of etching the SiO₂ film 21, the S102 film 21 remains on one long side of the element region but does not remain on the other long side. That is, both short sides of the element region are supported by the side surface of the support 22, and only one long side of the element region is supported by the side surface of the support 22.

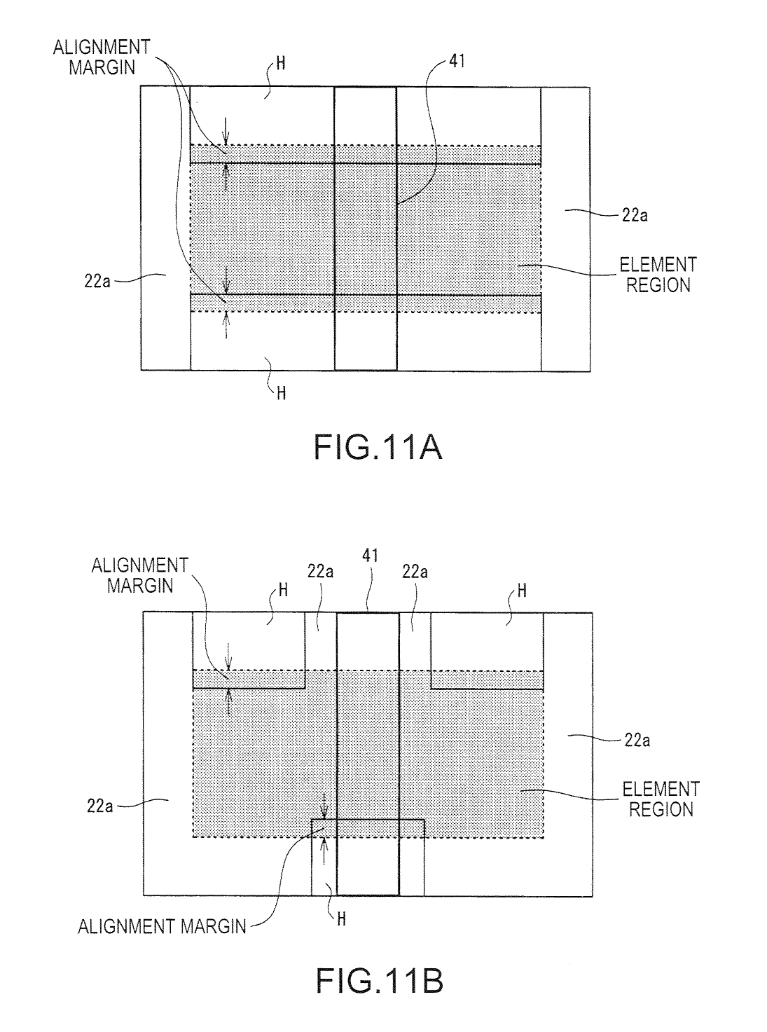

However, positions of legs of the support (hereunder referred also as “support legs 22a”) supporting the element region at the side surfaces thereof may vary. For example, referring to FIG. 11A, the support legs 22a are not arranged along the long sides of the element region but arranged only along the short sides of the element region. Alternatively, referring to FIG. 11B, the support legs 22a may be arranged continuously from the short sides to the long sides of the element region in plan view. In FIGS. 11A and 11B, the region surrounded by dotted lines is the element region.

In other words, if the planar shape of the element region is rectangular and the difference in length between the long and short sides is not extreme, the Si layer can be sufficiently supported with no support legs 22a at all along the long sides as shown in FIG. 11A. Also, if the support of the support legs 22a arranged as shown in FIG. 11A is not sufficient, it is possible to strengthen the support by increasing the area for arranging the support legs 22a or by dispersing the positions for arranging the legs 22a along the periphery of the element region.

Additionally all portions along the long sides of the element region at which the support legs 22a are not arranged become the SiGe removing holes H. In the second embodiment, also, the Si₃N₄ film covers the Si layer of the element region as does in the first embodiment. Therefore, with reference to FIGS. 11A and 11B, in the process of providing the SiGe removing hole H so as to planarly overlap with the end of the element region (at least by the distance of the alignment margin), it is also possible to prevent the Si layer at the overlapped region from being etched and to provide the SiGe removing hole H in a self-aligning manner. Accordingly, as in the embodiment 1, the variation that occurs in processing the element region can also be reduced in this embodiment.

The distance of the alignment margin mentioned above indicates a distance larger than an alignment margin allowed in the photolithography.

### 3. Other Embodiment

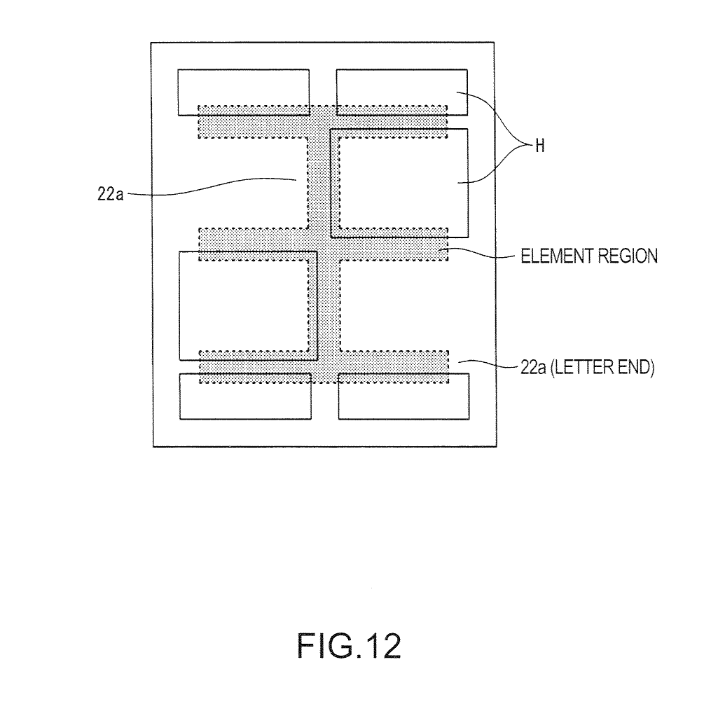

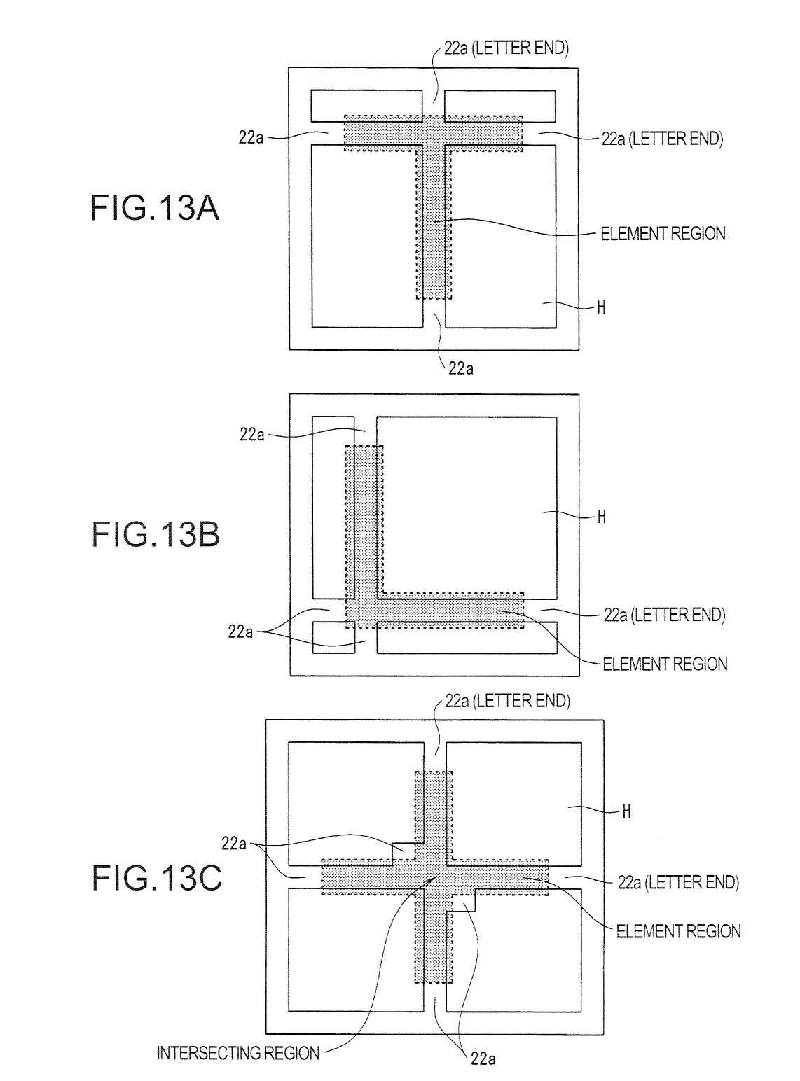

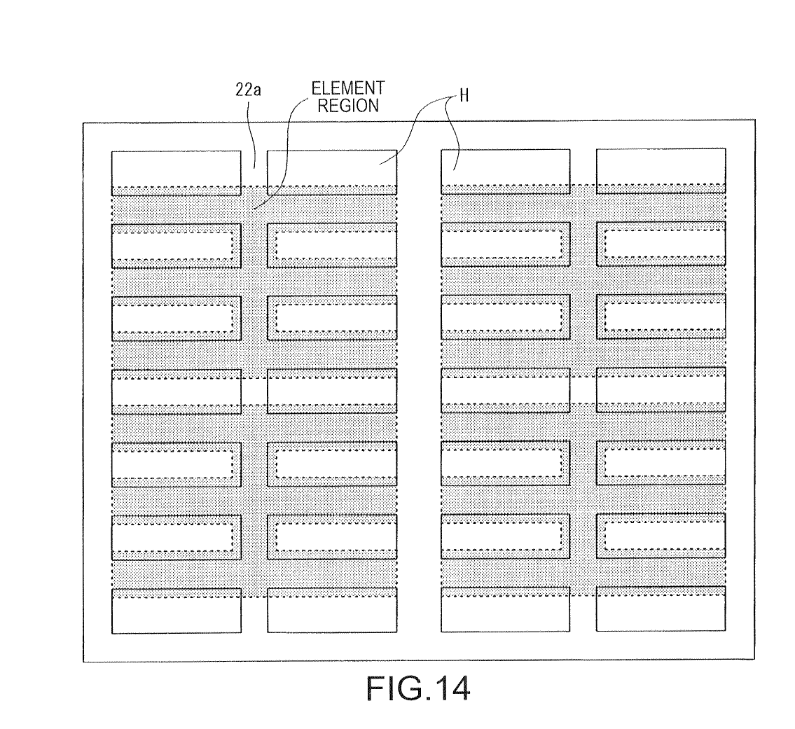

In the first and second embodiments, the planar shape of the element region is described as rectangle as an example. However, the element region may take other planar shapes that are applicable to the invention. For example, with reference to FIG. 12, the element region may take a planar shape of “tandem H.” Alternatively, referring to FIG. 13A to 13C, the planar shape of the element region may be the letter “T,” letter “L,” or “+”. Also, with reference to FIG. 14, the planar shape of the element region may be such that a plurality of H's are arranged in both X and Y directions. In FIGS. 12, 13A to 13C, and 14, the region surrounded by the dotted lines is the element region, and the region surrounded by the solid lines is the region where the SiGe removing hole H is to be provided (that is, the opened region of the resist pattern R1 used in the formation of the SiGe removing hole H).

In this embodiment of the invention, whether the planar shape of the element region is “tandem H.” letter “T,” letter “L,” or “+,” or any combination thereof, the Si₃N₄ film covers the Si layer of the element region in the process of providing the SiGe removing hole H. Accordingly, referring to FIGS. 12, 13A to 13C, and 14, in the process of providing the SiGe removing hole H so as to planarly overlap with the end of the element region (at least by the distance of the alignment margin), it is also possible to prevent the Si layer from being etched at the overlapped region and to provide the SiGe removing hole H in a self-aligning manner. As a result, similarly to the embodiments 1 and 2, the variation that occurs in processing the element region can also be reduced.

Additionally, as shown in FIGS. 12, 13A to 13C, and 14, if the planar shape of the element region is “tandem H,” letter “T,” letter “L,” or “+,” there is a possibility that the strength of support supporting the Si layer is weak at a letter end of the element region (that is, at the end of the element region in plan view). In this case, it is desirable to arrange the support legs 22a at the support holes adjacent to the letter ends of the element region so as to support the Si layer of the letter end from the side surface of the Si layer. Further, if the planar shape of the element region takes the shape of “+” as shown FIG. 13C, it is possible that the strength of support supporting the Si layer at the intersecting region of the “+” shaped center is weak. In this case, it is desirable to arrange the support legs 22a at the support holes adjacent to this intersecting region so as to support the Si layer at the intersecting region from the side surface of the Si layer. By these processes, it is possible to increase the support of the Si layer at the letter end and the intersecting region and to help prevent the Si layer from bending or peeling.

In the descriptions of the embodiments of the invention, the Si substrate 1 corresponds to the “semiconductor substrate”; the SiGe layer 11 corresponds to the “first semiconductor layer”; and the Si layer 13 corresponds to the “second semiconductor layer.” Also, the support hole h corresponds to the “first groove,” and the SiGe removing hole H corresponds to the “second groove.” Further, the Si₃N₄ film 18 corresponds to the “protection film,” and the SiO₂ film 21 corresponds to the “support film.”

What is claimed is:

1. A method for manufacturing a semiconductor device, comprising:
(a) stacking a first semiconductor layer and a second semiconductor layer serially on a semiconductor substrate;
(b) providing a protection film above the second semiconductor layer;
(c) providing a first groove that penetrates the protection film, the second semiconductor layer, and the first semiconductor layer and surrounds an element region in plan view so as to define a boundary between the element region and a remaining region, by partially etching the protection film, the second semiconductor layer, and the first semiconductor layer;
(d) providing a support film so as to fill the first groove and cover the second semiconductor layer,
(e) providing a second groove that provides a support including the support film and exposes the first semiconductor layer from under the second semiconductor layer, by partially etching the support film in a condition that the support film is more readily etched than the protection film; and
(f) providing a cavity between the semiconductor substrate and the second semiconductor layer of the element region by etching the first semiconductor layer via the second groove in a condition that the first semiconductor layer is more readily etched than the second semiconductor layer.

2. The method for manufacturing a semiconductor device according to claim 1, step (e) further including:
providing, on the support film, a resist pattern that opens both directly above a region for providing the second groove and directly above an end of the element region adjacent to the region for providing the second groove, the end being located at a side adjacent to the second groove; and
etching the support film using the resist pattern as a mask.

3. The method for manufacturing a semiconductor device according to claim 1, wherein:
the element region in plan view has any one shape out of a “tandem H” shape, a letter “T” shape, a letter “L” shape, and a “+” shape, or any combination thereof; and,
in the step (e), the support film remains in the first groove adjacent to a letter end of the element region.

4. The method for manufacturing a semiconductor device according to claim 1, wherein:
the element region in plan view includes a “+” shape; and,
in the step (e), the support film remains in the first groove adjacent to an intersecting region at a center of the “+” shape.
